(19) United States
(12) Patent Application Publication
(10) Pub. No.: US 2020/0286984 A1
(43) Pub. Date: Sep. 10, 2020

(54) CAPACITORS WITH FERROELECTRIC/ANTIFERROELECTRIC AND DIELECTRIC MATERIALS

(71) Applicant: Intel Corporation, Santa Clara, CA (US)

(72) Inventors: Sou-Chi Chang, Portland, OR (US); Chia-Ching Lin, Portland, OR (US); Ashish Verma Penumatcha, Hillsboro, OR (US); Uygar E. Avci, Portland, OR (US); Ian A. Young, Portland, OR (US)

(73) Assignee: Intel Corporation, Santa Clara, CA (US)

(21) Appl. No.: 16/296,035

(22) Filed: Mar. 7, 2019

(51) Int. Cl. H01L 49/02; H01L 27/108; H01L 27/11507

(52) U.S. Cl. CPC H01L 28/56; H01L 27/11507; H01L 27/10814; H01L 28/87

(57) ABSTRACT

Disclosed herein are capacitors with ferroelectric or antiferroelectric (FE/AFE) material and dielectric material, as well as related methods and devices. In some embodiments, a capacitor may include two electrodes, a layer of FE/AFE material between the electrodes, and a layer of dielectric material between the electrodes.

### BACKGROUND

Capacitors are used in many different electronic device designs. Some capacitors include a high-k dielectric material between two electrodes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIGS. 1-6 are side, cross-sectional views of example capacitors, in accordance with various embodiments.

FIGS. 7A and 7B are various views of an example capacitor, in accordance with various embodiments.

FIG. 8 is a schematic illustration of a memory device including capacitors in accordance with any of embodiments disclosed herein.

FIG. 9 is a flow diagram of a method of manufacturing a capacitor, in accordance with various embodiments.

FIG. 10 is a top view of a wafer and dies that may include a capacitor in accordance with any of the embodiments disclosed herein.

FIG. 11 is a side, cross-sectional view of an integrated circuit (IC) device that may include a capacitor in accordance with any of the embodiments disclosed herein.

FIG. 12 is a side, cross-sectional view of an IC package that may include a capacitor in accordance with various embodiments.

FIG. 13 is a side, cross-sectional view of an IC device assembly that may include a capacitor in accordance with any of the embodiments disclosed herein.

FIG. 14 is a block diagram of an example electrical device that may include a capacitor in accordance with any of the embodiments disclosed herein.

### DETAILED DESCRIPTION

Disclosed herein are capacitors with ferroelectric or antiferroelectric (FE/AFE) material and dielectric material, as well as related methods and devices. In some embodiments, a capacitor may include two electrodes, a layer of FE/AFE material between the electrodes, and a layer of dielectric material between the electrodes.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The drawings are not necessarily to scale. Although many of the drawings illustrate rectilinear structures with flat walls and right-angle corners, this is simply for ease of illustration, and actual devices made using these techniques will exhibit rounded corners, surface roughness, and other features.

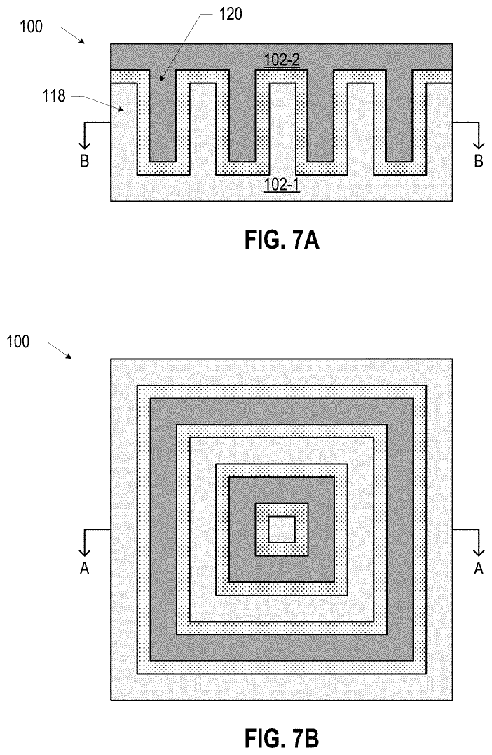

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “integrated circuit (IC) package” are synonymous. When used to describe a range of dimensions, the phrase “between X and Y” represents a range that includes X and Y. For convenience, the phrase “FIG. 7” may be used to refer to the collection of drawings of FIGS. 7A-7B.

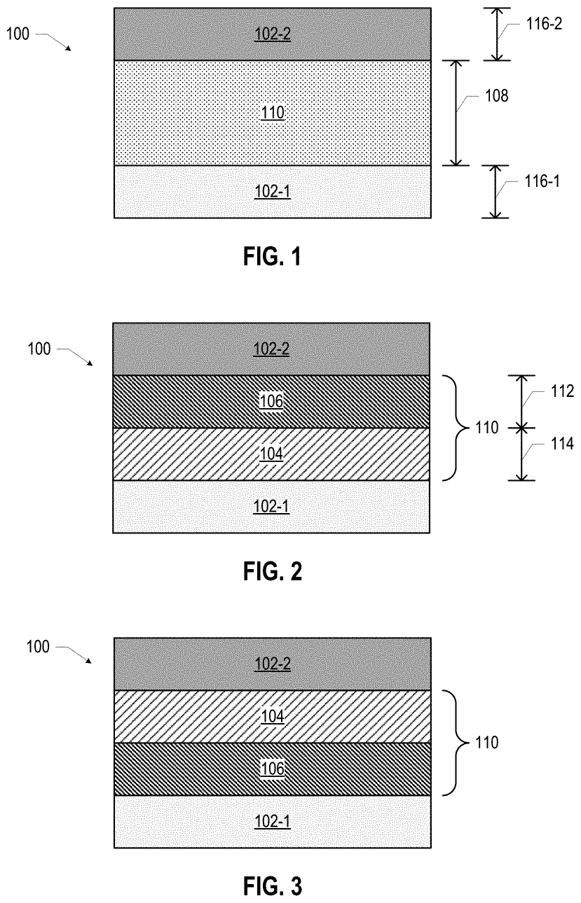

FIG. 1 is a side, cross-sectional view of a capacitor 100 including an inter-electrode stack 110 between an electrode 102-1 and an electrode 102-2. Although FIG. 1 depicts the electrodes 102 as being substantially planar, this is simply for ease of illustration, and the electrodes 102 may have any planar or non-planar shape (e.g., an electrode 102 may include trenches 118 and/or projections 120, as discussed below with reference to FIGS. 6 and 7). The electrodes 102 may have any suitable material composition. In some embodiments, one or more of the electrodes 102 may include titanium and nitrogen (e.g., in the form of titanium nitride), titanium and silicon and nitrogen (e.g., in the form of titanium silicon nitride), tantalum and nitrogen (e.g., in the form of tantalum nitride), copper, aluminum, gold, tungsten, cobalt, platinum, iridium or ruthenium. In some embodiments, the electrode 102-1 and the electrode 102-2 may have the same material composition, while in other embodiments, the electrode 102-1 may have a different material composition than the electrode 102-2. In some embodiments in which the capacitor 100 is included in a die (e.g., as discussed below with reference to FIG. 10), the electrode 102-1 may be closer to the substrate and/or the device layer than the electrode 102-2 is to the substrate and/or the device layer.

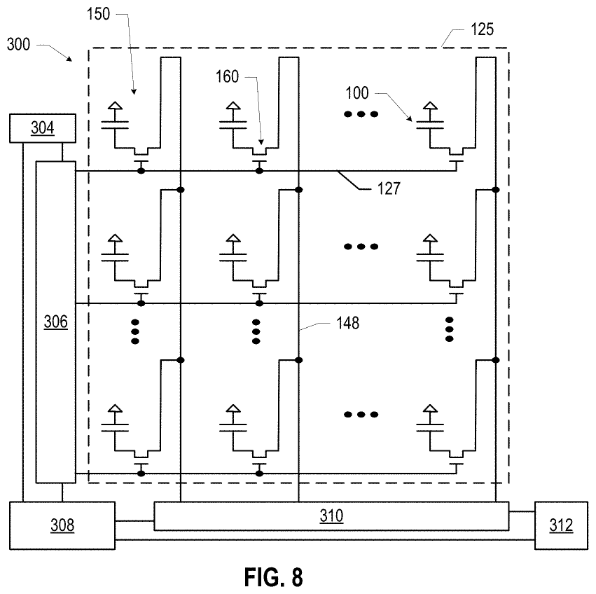

The inter-electrode stack 110 may include one or more layers of a ferroelectric material or an antiferroelectric material 104 and one or more layers of a dielectric material 106, in any suitable arrangement (discussed further below). As used herein, an “FE/AFE material” or an “FE/AFE material 104” includes a ferroelectric material or an antiferroelectric material. Capacitors 100 including an inter-electrode stack 110 with an FE/AFE material 104 and a dielectric material 106 may achieve higher capacitance than achievable by conventional capacitors with a high-k dielectric between the electrodes. This increased capacitance may be the result of depolarization effects of the FE/AFE material 104 enhanced by the presence of the dielectric material 106. The capacitors 100 may thus be particularly useful in applications in which high capacitance improves performance. For example, the capacitors 100 disclosed herein may be utilized as a decoupling capacitor in a circuit to mitigate voltage transients (e.g., supply grid voltage transients). In another example, the capacitors 100 disclosed herein may be utilized in a memory device (e.g., a one transistor-one capacitor (1T-1C) memory structure, as discussed further below with reference to FIG. 8).

An FE/AFE material 104 in a capacitor 100 may have any suitable material composition. In some embodiments, an FE/AFE material 104 may include a ferroelectric material (i.e., a material that exhibits a spontaneous electric polarization that can be reversed by the application of an external electric field). In some such embodiments, the FE/AFE material 104 may include silicon, lanthanum, nitrogen, aluminum, zirconium, germanium, or hafnium and oxygen and yttrium (e.g., in the form of yttrium-doped hafnium oxide). In some embodiments, the FE/AFE material 104 may include a perovskite ferroelectric. In some such embodiments, the FE/AFE material 104 may include nitrogen, hydrogen, phosphorous, and oxygen (e.g., in the form of ammonium dihydrogen phosphate); potassium, hydrogen, phosphorous, and oxygen (e.g., in the form of potassium dihydrogen phosphate); lithium, niobium, and oxygen (e.g., in the form of lithium niobate); lithium, tantalum, and oxygen (e.g., in the form of lithium tantalate); barium, titanium, and oxygen (e.g., in the form of barium titanate); lead, titanium, and oxygen (e.g., in the form of lead titanate); lead, zirconium, titanium, and oxygen (e.g., in the form of lead zirconate titanate); lead, zirconium, and oxygen (e.g., in the form of lead zirconate); lanthanum, titanium, and oxygen (e.g., in the form of lanthanum titanate); lead, lanthanum, titanium, and oxygen (e.g., in the form of lead lanthanate titanate); lead, lanthanum, zirconium, titanium, and oxygen (e.g., in the form of lanthanum-modified lead zirconate titanate); lanthanum, zirconium, titanium, and oxygen (e.g., in the form of lanthanum zirconate titanate); lead, lanthanum, zirconium, and oxygen (e.g., in the form of lead lanthanate zirconate); lanthanum, zirconium, and oxygen (e.g., in the form of lanthanum zirconate); or lanthanum, titanium, and oxygen (e.g., in the form of lanthanum titanate).

In some embodiments, an FE/AFE material 104 may include an antiferroelectric material (i.e., a material that exhibits a dielectric-ferroelectric phase transition when the applied electric field is larger than the coercive field). In some such embodiments, the FE/AFE material 104 may include silicon; lanthanum; nitrogen; aluminum; zirconium; germanium; zirconium and oxygen (e.g., in the form of zirconium oxide); or hafnium and oxygen and yttrium (e.g., in the form of yttrium-doped hafnium oxide). When atomic layer deposition (ALD) is used to grow the FE/AFE material 104, doped hafnium oxide may have a superlattice structure. In embodiments in which a capacitor 100 includes multiple layers of FE/AFE material 104 (e.g., as discussed below with reference to FIG. 5), the different layers may have the same material composition, or different material compositions.

The dielectric material 106 may have a different material composition than the FE/AFE material 104. In some embodiments, the dielectric material 106 may include silicon and oxygen (e.g., in the form of silicon oxide); aluminum and oxygen (e.g., in the form of aluminum oxide); hafnium and oxygen (e.g., in the form of hafnium oxide); tantalum and oxygen (e.g., in the form of tantalum oxide); or lanthanum and oxygen (e.g., in the form of lanthanum oxide). In embodiments in which a capacitor 100 includes multiple layers of dielectric material 106 (e.g., as discussed below with reference to FIGS. 5 and 6), the different layers may have the same material composition, or different material compositions.

A capacitor 100 may have any suitable dimensions. In some embodiments, a thickness 116-1 of an electrode 102-1 may be between 10 nanometers and 60 nanometers; the thickness 116-2 of the electrode 102-2 may be in the same range. In some embodiments, the thickness 116-1 may be the same as the thickness 116-2, while in other embodiments, the thickness 116-1 may be different than the thickness 116-2. In some embodiments, an electrode 102 may not have a single thickness 116, but may instead have different regions with different thicknesses (e.g., as discussed below with reference to FIGS. 6 and 7). In some embodiments, a thickness 108 of the inter-electrode stack 110 may be between 2 nanometers and 20 nanometers. Like the electrodes 102, in some embodiments, an inter-electrode stack 110 may not have a single thickness 108, but may instead have different regions with different thicknesses.

FIGS. 2-7 illustrate example capacitors 100 including FE/AFE material 104 and dielectric material 106. Any suitable ones of the features discussed with reference to any of FIGS. 1-7 herein may be combined with any other features to form a capacitor 100. For example, as discussed further below, FIG. 2 illustrates an embodiment in which a layer of FE/AFE material 104 is between the electrode 102-1 and a layer of dielectric material 106, and FIG. 6 illustrates an embodiment in which the electrode 102-1 includes a trench 118. These features of FIGS. 2 and 6 may be combined so that a capacitor 100, in accordance with the present disclosure, includes a layer of FE/AFE material 104 between the electrode 102-1 and a layer of dielectric material 106, and the electrode 102-1 includes a trench 118. This particular combination is simply an example, and any combination may be used. A number of elements of FIG. 1 are shared with FIGS. 2-7; for ease of discussion, a description of these elements is not repeated, and these elements may take the form of any of the embodiments disclosed herein.

As noted above, a capacitor 100 may include one or more layers of FE/AFE material 104 and one or more layers of dielectric material 106 arranged in any suitable manner in the inter-electrode stack 110. FIG. 2 depicts an embodiment in which a layer of FE/AFE material 104 is between the electrode 102-1 and a layer of dielectric material 106, and the layer of dielectric material 106 is between the layer of FE/AFE material 104 and the electrode 102-2. The thickness 114 of a layer of FE/AFE material 104 in the capacitor 100 of FIG. 2 (or any of the capacitors 100 disclosed herein) may be between 1 nanometer and 10 nanometers (e.g., between 3 nanometers and 10 nanometers, or between 5 nanometers and 10 nanometers). The thickness 112 of a layer of dielectric material 106 in the capacitor 100 of FIG. 2 (or any of the capacitors 100 disclosed herein) may be between 1 nanometer and 5 nanometers). FIG. 3 depicts an embodiment in which a layer of dielectric material 106 is between the electrode 102-1 and a layer of FE/AFE material 104, and the layer of FE/AFE material 104 is between the layer of dielectric material 106 and the electrode 102-2.

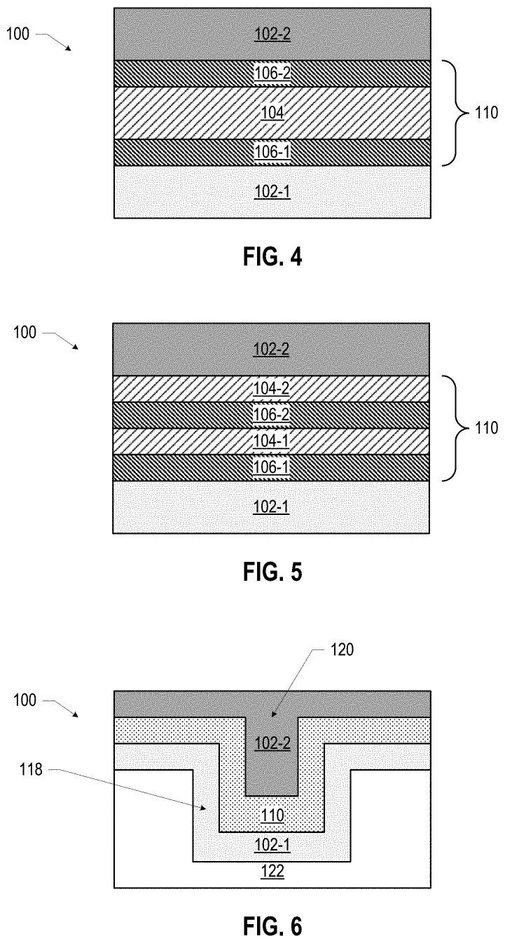

FIGS. 4 and 5 illustrate capacitors 100 including multiple layers of FE/AFE material 104 and/or multiple layers of dielectric material 106. FIG. 4 illustrates a capacitor 100 in which the inter-electrode stack 110 includes a layer of FE/AFE material 104 between a layer of dielectric material 106-1 and a layer of dielectric material 106-2. A capacitor 100 may instead include an inter-electrode stack 110 in which a layer of dielectric material 106 is between two layers of FE/AFE material 104 (not shown). FIG. 5 illustrates a capacitor 100 with an inter-electrode stack 110 that includes a layer of dielectric material 106-1, a layer of FE/AFE material 104-1, a layer of dielectric material 106-2, and a layer of FE/AFE material 104-2. In other embodiments, the inter-electrode stack 110 of FIG. 5 may be inverted so that the layer of dielectric material 104-2 is closer to the electrode 102-1 than to the electrode 102-2. Further, an inter-electrode stack 110 may include more than two layers of FE/AFE material 104 and/or more than two layers of dielectric material 106.

As noted above, in some embodiments, the electrodes 102 of a capacitor 100 may be planar. In other embodiments, one or more of the electrodes 102 may be non-planar. For example, FIG. 6 illustrates a capacitor 100 in which the electrode 102-1 includes a trench 118 into which the inter-electrode stack 110 (which may take the form of any of the inter-electrode stacks 110 disclosed herein) extends. In the embodiment of FIG. 6, the inter-electrode stack 110 is conformal over an upper surface of the electrode 102-1. The electrode 102-2 includes a projection 120 that extends into the trench 118, and may have a substantially planar upper surface. In the embodiment of FIG. 6, the electrode 102-2 is shown as being substantially conformal on the upper surface of a support 122 (which may include, for example, a dielectric material).

FIG. 7 illustrates a capacitor in which the electrode 102-1 includes multiple trenches 118 into which the inter-electrode stack 110 (which may take the form of any of the inter-electrode stacks 110 disclosed herein) extends. FIG. 7A is a side, cross-sectional view through the section A-A of FIG. 7B, and FIG. 7B is a top, cross-sectional view through the section B-B of FIG. 7A. In the embodiment of FIG. 7, the inter-electrode stack 110 is conformal over an upper surface of the electrode 102-1. The electrode 102-2 includes multiple projections 120 that extends into associated ones of the trenches 118 in an interdigitated fashion, and may have a substantially planar upper surface.

As noted above, in some embodiments, the capacitors 100 disclosed herein may be included in a memory device. FIG. 8 is a schematic illustration of a memory device 300 including a memory array 125 having 1T-1C memory cells 150 with capacitors 100 and transistors 160 (e.g., any of the transistors discussed below with reference to FIG. 10), in accordance with various embodiments. The capacitors 100 may take the form of any of the embodiments disclosed herein. The memory device 300 may be a dynamic random access memory (DRAM) device. The memory device 300 of FIG. 8 may be a bidirectional cross-point array in which each column is associated with a bit line 148 driven by column select circuitry 310. Each row may be associated with a word line 127 driven by row select circuitry 306. During operation, read/write control circuitry 308 may receive memory access requests (e.g., from one or more processing devices or communication chips of an electrical device, such as the electrical device 1800 discussed below), and may respond by generating an appropriate control signal (e.g., read, write 0, or write 1), as known in the art. The read/write control circuitry 308 may control the row select circuitry 306 and the column select circuitry 310 to select the desired memory cell(s) 150. Voltage supplies 304 and 312 may be controlled to provide the voltage(s) necessary to bias the memory array 125 to facilitate the requested action on one or more memory cells 150. Row select circuitry 306 and column select circuitry 310 may apply appropriate voltages across the memory array 125 to access the selected memory cells 150 (e.g., by providing appropriate voltages to the memory cells 150 to allow the desired transistors 160 to conduct current). The read/write control circuit 308 may include sense amplifier circuitry, as known in the art. Row select circuitry 306, column select circuitry 310, and read/write control circuitry 308 may be implemented using any devices and techniques known in the art. The memory device 300 may be included in a die (e.g., any of the dies 1502 discussed below) and may be part of an integrated circuit (IC) device (e.g., any of the IC devices 1600 discussed below).

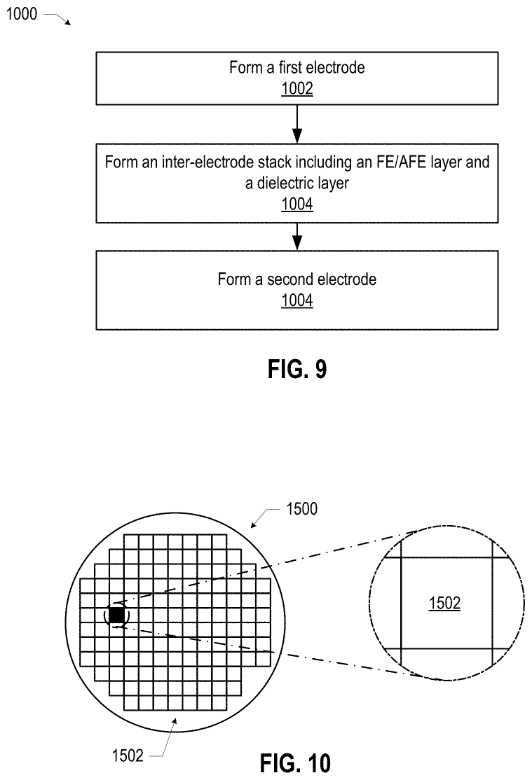

FIG. 9 is a flow diagram of a method 1000 of manufacturing a capacitor, in accordance with various embodiments. Although the operations of the method 1000 may be illustrated with reference to particular embodiments of the capacitors 100 disclosed herein, the method 1000 may be used to form any suitable capacitor. Operations are illustrated once each and in a particular order in FIG. 9, but the operations may be reordered and/or repeated as desired (e.g., with different operations performed in parallel when manufacturing multiple electronic components simultaneously).

At 1002, a first electrode may be formed. For example, an electrode 102-1 may be formed using any suitable deposition and patterning technique.

At 1004, an inter-electrode stack may be formed. The inter-electrode stack may include an FE/AFE layer and a dielectric layer. For example, an inter-electrode stack 110 may be formed on the electrode 102-1, and may include one or more layers of FE/AFE material 104 and one or more layers of dielectric material 106.

At 1006, a second electrode may be formed. For example, an electrode 102-2 may be formed on the inter-electrode stack 110 so that the electrodes 102-1 and 102-2 “sandwich” the inter-electrode stack 110.

The capacitors 100 disclosed herein may be included in any suitable electronic component. FIGS. 10-14 illustrate various examples of apparatuses that may include any of the capacitors 100 disclosed herein, or may be included in an IC package that also includes any of the capacitors 100 disclosed herein.

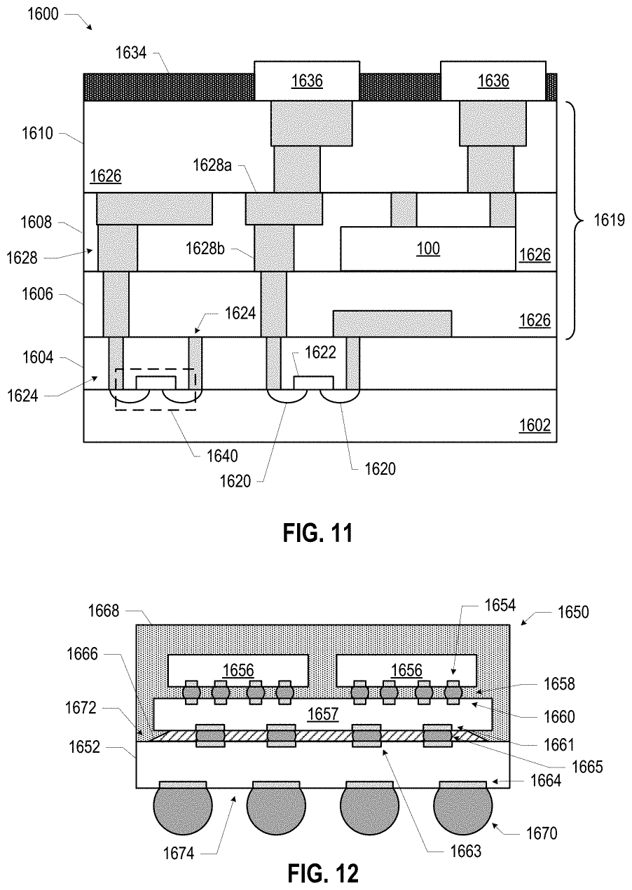

FIG. 10 is a top view of a wafer 1500 and dies 1502 that may include one or more capacitors 100, or may be included in an IC package including one or more capacitors 100 (e.g., as discussed below with reference to FIG. 12) in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more capacitors 100 (e.g., as discussed below with reference to FIG. 11), one or more transistors (e.g., some of the transistors 1640 of FIG. 11, discussed below) and/or supporting circuitry to route electrical signals to the transistors, as well as any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 14) or other logic that is configured to store information in the memory devices or execute instructions stored in the memory array.

FIG. 11 is a side, cross-sectional view of an IC device 1600 that may include one or more capacitors 100, or may be included in an IC package including one or more capacitors 100 (e.g., as discussed below with reference to FIG. 12), in accordance with any of the embodiments disclosed herein. One or more of the IC devices 1600 may be included in one or more dies 1502 (FIG. 10). The IC device 1600 may be formed on a substrate 1602 (e.g., the wafer 1500 of FIG. 10) and may be included in a die (e.g., the die 1502 of FIG. 10). The substrate 1602 may be a semiconductor substrate composed of semiconductor material systems including, for example, n-type or p-type materials systems (or a combination of both). The substrate 1602 may include, for example, a crystalline substrate formed using a bulk silicon or a silicon-on-insulator (SOI) substructure. In some embodiments, the substrate 1602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 1602. Although a few examples of materials from which the substrate 1602 may be formed are described here, any material that may serve as a foundation for an IC device 1600 may be used. The substrate 1602 may be part of a singulated die (e.g., the dies 1502 of FIG. 10) or a wafer (e.g., the wafer 1500 of FIG. 10).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 11 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion-implantation process. In the latter process, the substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

In some embodiments, the device layer 1604 may include one or more capacitors 100, in addition to or instead of transistors 1640. No capacitors 100 are depicted in the device layer 1604 for ease of illustration, but any number and structure of capacitors 100 may be included in a device layer 1604. A capacitor 100 included in a device layer 1604 may be referred to as a “front-end” device. In some embodiments, the IC device 1600 may not include any front-end capacitors 100. One or more capacitors 100 in the device layer 1604 may be coupled to any suitable other ones of the devices in the device layer 1604, to any devices in the metallization stack 1619 (discussed below), and/or to one or more of the conductive contacts 1636 (discussed below).

Electrical signals, such as power and/or input/output (I/O) signals, may be routed to and/or from the devices (e.g., the transistors 1640 and/or capacitors 100) of the device layer 1604 through one or more interconnect layers disposed on the device layer 1604 (illustrated in FIG. 11 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600. In some embodiments, one or more capacitors 100 may be disposed in one or more of the interconnect layers 1606-1610, in accordance with any of the techniques disclosed herein. FIG. 11 illustrates a single capacitors 100 in the interconnect layer 1608 for illustration purposes, but any number and structure of capacitors 100 may be included in any one or more of the layers in a metallization stack 1619. A capacitors 100 included in the metallization stack 1619 may be referred to as a “back-end” device. In some embodiments, the IC device 1600 may not include any back-end capacitors 100; in some embodiments, the IC device 1600 may include both front- and back-end capacitors 100. One or more capacitors 100 in the metallization stack 1619 may be coupled to any suitable ones of the devices in the device layer 1604, and/or to one or more of the conductive contacts 1636 (discussed below).

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 11). Although a particular number of interconnect layers 1606-1610 is depicted in FIG. 11, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the substrate 1602 upon which the device layer 1604 is formed. For example, the lines 1628a may route electrical signals in a direction in and out of the page from the perspective of FIG. 11. The vias 1628b may be arranged to route electrical signals in a direction of a plane that is substantially perpendicular to the surface of the substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 11. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 may be formed above the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 11, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

FIG. 12 is a side, cross-sectional view of an example IC package 1650 that may include one or more capacitors 100. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the interconnects 1628 discussed above with reference to FIG. 11. No capacitors 100 are depicted in the package substrate 1652 for ease of illustration, but any number and location of capacitors 100 (with any suitable structure) may be included in a package substrate 1652. In some embodiments, no capacitors 100 may be included in the package substrate 1652.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 or to the capacitors 100 (or to other devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 12 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 12 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

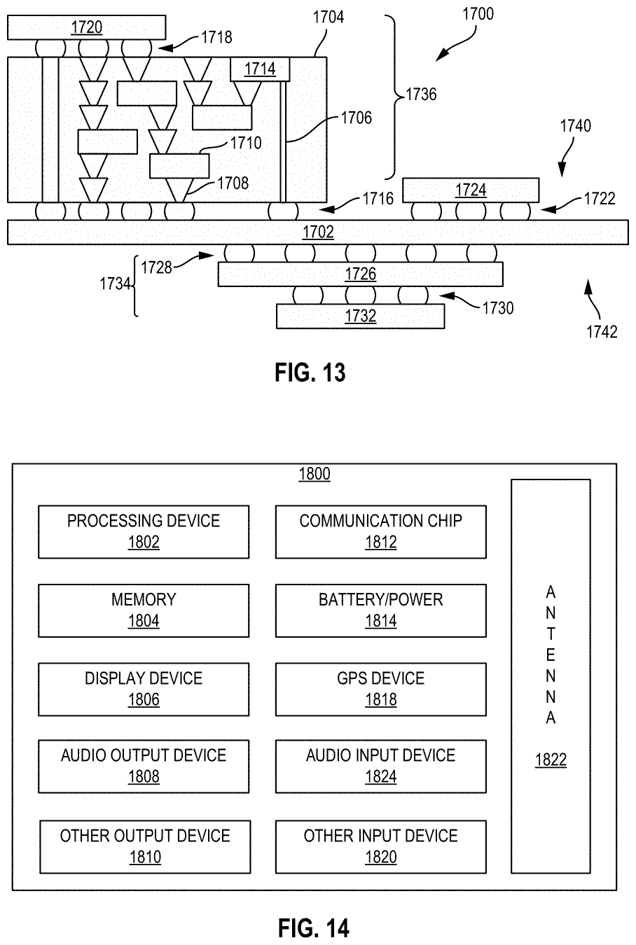

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 12 are solder balls (e.g., for a ball grid array arrangement), but any suitable second-level interconnects 16770 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 13.

The dies 1656 may take the form of any of the embodiments of the die 1502 discussed herein (e.g., may include any of the embodiments of the IC device 1600). In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high bandwidth memory). In some embodiments, the die 1656 may include one or more capacitors 100 (e.g., as discussed above with reference to FIG. 10 and FIG. 11); in other embodiments, the die 1656 may not include any capacitors 100.

Although the IC package 1650 illustrated in FIG. 12 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 12, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 13 is a side, cross-sectional view of an IC device assembly 1700 that may include one or more IC packages or other electronic components (e.g., a die) including one or more capacitors 100, in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 12 (e.g., may include one or more capacitors 100 in a package substrate 1652 or in a die).

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 13 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 13), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 13, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 10), an IC device (e.g., the IC device 1600 of FIG. 11), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 13, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art. In some embodiments, the package interposer 1704 may include one or more capacitors 100.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 13 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 14 is a block diagram of an example electrical device 1800 that may include one or more capacitors 100, in accordance with any of the embodiments disclosed herein. For example, any suitable ones of the components of the electrical device 1800 may include one or more of the IC device assemblies 1700, IC packages 1650, IC devices 1600, or dies 1502 disclosed herein. A number of components are illustrated in FIG. 14 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 14, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 is a capacitor, including: a first electrode; a second electrode; and an inter-electrode stack between the first electrode and the second electrode, wherein the inter-electrode stack includes a first layer including a first material, the inter-electrode stack includes a second layer including a second material, the first material is a dielectric material, and the second material is a ferroelectric material or an antiferroelectric material.

Example 2 includes the subject matter of Example 1, and further specifies that the first material includes silicon, aluminum, hafnium, tantalum, or lanthanum.

Example 3 includes the subject matter of Example 2, and further specifies that the first material further includes oxygen.

Example 4 includes the subject matter of any of Examples 1-3, and further specifies that the second material includes silicon.

Example 5 includes the subject matter of any of Examples 1-3, and further specifies that the second material includes lanthanum.

Example 6 includes the subject matter of any of Examples 1-3, and further specifies that the second material includes nitrogen.

Example 7 includes the subject matter of any of Examples 1-3, and further specifies that the second material includes aluminum.

Example 8 includes the subject matter of any of Examples 1-3, and further specifies that the second material includes zirconium, or zirconium and oxygen.

Example 9 includes the subject matter of any of Examples 1-3, and further specifies that the second material includes germanium.

Example 10 includes the subject matter of any of Examples 1-3, and further specifies that the second material includes hafnium and yttrium.

Example 11 includes the subject matter of any of Examples 1-10, and further specifies that the second material is a ferroelectric material.

Example 12 includes the subject matter of Example 11, and further specifies that the second material includes a perovskite ferroelectric.

Example 13 includes the subject matter of any of Examples 1-10, and further specifies that the second material is an antiferroelectric material.

Example 14 includes the subject matter of any of Examples 1-13, and further specifies that a thickness of the second layer is less than 10 nanometers.

Example 15 includes the subject matter of any of Examples 1-13, and further specifies that a thickness of the second layer is less than 5 nanometers.

Example 16 includes the subject matter of any of Examples 1-13, and further specifies that a thickness of the second layer is less than 3 nanometers.

Example 17 includes the subject matter of any of Examples 1-13, and further specifies that a thickness of the second layer is less than 1 nanometer.

Example 18 includes the subject matter of any of Examples 1-17, and further specifies that a thickness of the first layer is between 1 nanometer and 5 nanometers.

Example 19 includes the subject matter of any of Examples 1-18, and further specifies that the inter-electrode stack further includes a third layer, the second layer is between the first layer and the third layer, and the third layer includes a dielectric material.

Example 20 includes the subject matter of Example 19, and further specifies that the third layer includes the first material.

Example 21 includes the subject matter of any of Examples 19-20, and further specifies that the inter-electrode stack further includes a fourth layer, the third layer is between the second layer and the fourth layer, and the fourth layer includes a ferroelectric material or an antiferroelectric material.

Example 22 includes the subject matter of Example 21, and further specifies that the fourth layer includes the second material.

Example 23 includes the subject matter of any of Examples 1-18, and further specifies that the inter-electrode stack further includes a third layer, the first layer is between the second layer and the third layer, and the third layer includes a ferroelectric material or an antiferroelectric material.

Example 24 includes the subject matter of Example 23, and further specifies that the third layer includes the second material.

Example 25 includes the subject matter of any of Examples 1-24, and further specifies that the first electrode includes titanium and nitrogen.

Example 26 includes the subject matter of Example 25, and further specifies that the first electrode further includes silicon.

Example 27 includes the subject matter of any of Examples 1-24, and further specifies that the first electrode includes tantalum and nitrogen.

Example 28 includes the subject matter of any of Examples 1-24, and further specifies that the first electrode includes copper, aluminum, gold, tungsten, cobalt, platinum, iridium, or ruthenium.

Example 29 includes the subject matter of any of Examples 1-28, and further specifies that the second electrode has a same material composition as the first electrode.

Example 30 includes the subject matter of any of Examples 1-29, and further specifies that the first electrode has a thickness between 10 nanometers and 50 nanometers.

Example 31 includes the subject matter of Example 30, and further specifies that the second electrode has a thickness between 10 nanometers and 50 nanometers.

Example 32 includes the subject matter of any of Examples 1-31, and further specifies that the first electrode is planar, and the second electrode is planar.

Example 33 includes the subject matter of any of Examples 1-31, and further specifies that the first electrode includes a trench and the inter-electrode stack is at least partially in the trench.

Example 34 includes the subject matter of Example 33, and further specifies that the second electrode includes a projection that extends at least partially into the trench.

Example 35 includes the subject matter of any of Examples 1-31, and further specifies that the first electrode includes a plurality of trenches and the inter-electrode stack is at least partially in the plurality of trenches.

Example 36 includes the subject matter of Example 35, and further specifies that the second electrode includes a plurality of projections, wherein an individual projection extends at least partially into an associated individual trench.

Example 37 is an integrated circuit (IC) die, including: a capacitor, including a first electrode, a second electrode, and an inter-electrode stack between the first electrode and the second electrode, wherein the inter-electrode stack includes a first layer including a first material, the inter-electrode stack includes a second layer including a second material, the first material is a dielectric material, and the second material is a ferroelectric material or an antiferroelectric material.

Example 38 includes the subject matter of Example 37 wherein the first material includes silicon, aluminum, hafnium, tantalum, or lanthanum.

Example 39 includes the subject matter of Example 38, and further specifies that the first material further includes oxygen.

Example 40 includes the subject matter of any of Examples 37-39, and further specifies that the second material includes silicon.

Example 41 includes the subject matter of any of Examples 37-39, and further specifies that the second material includes lanthanum.

Example 42 includes the subject matter of any of Examples 37-39, and further specifies that the second material includes nitrogen.

Example 43 includes the subject matter of any of Examples 37-39, and further specifies that the second material includes aluminum.

Example 44 includes the subject matter of any of Examples 37-39, and further specifies that the second material includes zirconium, or zirconium and oxygen.

Example 45 includes the subject matter of any of Examples 37-39, and further specifies that the second material includes germanium.

Example 46 includes the subject matter of any of Examples 37-39, and further specifies that the second material includes hafnium and yttrium.

Example 47 includes the subject matter of any of Examples 37-46, and further specifies that the second material is a ferroelectric material.

Example 48 includes the subject matter of Example 47, and further specifies that the second material includes a perovskite ferroelectric.

Example 49 includes the subject matter of any of Examples 37-46, and further specifies that the second material is an antiferroelectric material.

Example 50 includes the subject matter of any of Examples 37-49, and further specifies that a thickness of the second layer is less than 10 nanometers.

Example 51 includes the subject matter of any of Examples 37-49, and further specifies that a thickness of the second layer is less than 5 nanometers.

Example 52 includes the subject matter of any of Examples 37-49, and further specifies that a thickness of the second layer is less than 39 nanometers.

Example 53 includes the subject matter of any of Examples 37-49, and further specifies that a thickness of the second layer is less than 1 nanometer.

Example 54 includes the subject matter of any of Examples 37-53, and further specifies that a thickness of the first layer is between 1 nanometer and 5 nanometers.

Example 55 includes the subject matter of any of Examples 37-54, and further specifies that the inter-electrode stack further includes a third layer, the second layer is between the first layer and the third layer, and the third layer includes a dielectric material.

Example 56 includes the subject matter of Example 55, and further specifies that the third layer includes the first material.

Example 57 includes the subject matter of any of Examples 55-56, and further specifies that the inter-electrode stack further includes a fourth layer, the third layer is between the second layer and the fourth layer, and the fourth layer includes a ferroelectric material or an antiferroelectric material.

Example 58 includes the subject matter of Example 57, and further specifies that the fourth layer includes the second material.

Example 59 includes the subject matter of any of Examples 37-54, and further specifies that the inter-electrode stack further includes a third layer, the first layer is between the second layer and the third layer, and the third layer includes a ferroelectric material or an antiferroelectric material.

Example 60 includes the subject matter of Example 59, and further specifies that the third layer includes the second material.

Example 61 includes the subject matter of any of Examples 37-60, and further specifies that the first electrode includes titanium and nitrogen.

Example 62 includes the subject matter of Example 61, and further specifies that the first electrode further includes silicon.

Example 63 includes the subject matter of any of Examples 37-60, and further specifies that the first electrode includes tantalum and nitrogen.

Example 64 includes the subject matter of any of Examples 37-60, and further specifies that the first electrode includes copper, aluminum, gold, tungsten, cobalt, platinum, iridium, or ruthenium.

Example 65 includes the subject matter of any of Examples 37-64, and further specifies that the second electrode has a same material composition as the first electrode.

Example 66 includes the subject matter of any of Examples 37-65, and further specifies that the first electrode has a thickness between 10 nanometers and 50 nanometers.

Example 67 includes the subject matter of Example 66, and further specifies that the second electrode has a thickness between 10 nanometers and 50 nanometers.

Example 68 includes the subject matter of any of Examples 37-67, and further specifies that the first electrode is planar, and the second electrode is planar.

Example 69 includes the subject matter of any of Examples 37-67, and further specifies that the first electrode includes a trench and the inter-electrode stack is at least partially in the trench.

Example 70 includes the subject matter of Example 69, and further specifies that the second electrode includes a projection that extends at least partially into the trench.

Example 71 includes the subject matter of any of Examples 37-67, and further specifies that the first electrode includes a plurality of trenches and the inter-electrode stack is at least partially in the plurality of trenches.

Example 72 includes the subject matter of Example 71, and further specifies that the second electrode includes a plurality of projections, wherein an individual projection extends at least partially into an associated individual trench.

Example 73 includes the subject matter of any of Examples 37-72, and further includes: a transistor coupled to the capacitor.

Example 74 includes the subject matter of Example 73, and further specifies that the transistor and the capacitor are part of a memory cell.

Example 75 includes the subject matter of Example 74, and further specifies that the memory cell is a 1T-1C memory cell.

Example 76 includes the subject matter of any of Examples 73-75, and further specifies that the transistor is included in a front-end of the IC die.

Example 77 includes the subject matter of any of Examples 73-75, and further specifies that the transistor is included in a back-end of the IC die.

Example 78 is a computing device, including: an integrated circuit (IC) package including a memory device, wherein the memory device includes a plurality of memory cells, and an individual one of the memory cells includes a transistor and a capacitor, wherein the capacitor includes two electrodes, a layer of ferroelectric or antiferroelectric material between the electrodes, and a layer of dielectric material between the electrodes.

Example 79 includes the subject matter of Example 78 wherein the dielectric material includes silicon, aluminum, hafnium, tantalum, or lanthanum.

Example 80 includes the subject matter of Example 79, and further specifies that the dielectric material further includes oxygen.

Example 81 includes the subject matter of any of Examples 78-80, and further specifies that the ferroelectric or antiferroelectric material includes silicon.

Example 82 includes the subject matter of any of Examples 78-80, and further specifies that the ferroelectric or antiferroelectric material includes lanthanum.

Example 83 includes the subject matter of any of Examples 78-80, and further specifies that the ferroelectric or antiferroelectric material includes nitrogen.

Example 84 includes the subject matter of any of Examples 78-80, and further specifies that the ferroelectric or antiferroelectric material includes aluminum.

Example 85 includes the subject matter of any of Examples 78-80, and further specifies that the ferroelectric or antiferroelectric material includes zirconium, or zirconium and oxygen.

Example 86 includes the subject matter of any of Examples 78-80, and further specifies that the ferroelectric or antiferroelectric material includes germanium.

Example 87 includes the subject matter of any of Examples 78-80, and further specifies that the ferroelectric or antiferroelectric material includes hafnium and yttrium.

Example 88 includes the subject matter of any of Examples 78-87, and further specifies that the ferroelectric or antiferroelectric material is a ferroelectric material.

Example 89 includes the subject matter of Example 88, and further specifies that the ferroelectric or antiferroelectric material includes a perovskite ferroelectric.

Example 90 includes the subject matter of any of Examples 78-87, and further specifies that the ferroelectric or antiferroelectric material is an antiferroelectric material.

Example 91 includes the subject matter of any of Examples 78-90, and further specifies that a thickness of the layer of ferroelectric or antiferroelectric is less than 10 nanometers.

Example 92 includes the subject matter of any of Examples 78-90, and further specifies that a thickness of the layer of ferroelectric or antiferroelectric is less than 5 nanometers.

Example 93 includes the subject matter of any of Examples 78-90, and further specifies that a thickness of the layer of ferroelectric or antiferroelectric is less than 80 nanometers.

Example 94 includes the subject matter of any of Examples 78-90, and further specifies that a thickness of the layer of ferroelectric or antiferroelectric is less than 1 nanometer.

Example 95 includes the subject matter of any of Examples 78-94, and further specifies that a thickness of the layer of dielectric material is between 1 nanometer and 5 nanometers.

Example 96 includes the subject matter of any of Examples 78-95, and further specifies that the capacitor includes multiple layers of dielectric material sandwiching the layer of ferroelectric or antiferroelectric material.

Example 97 includes the subject matter of Example 96, and further specifies that the multiple layers of dielectric material have a same material composition.

Example 98 includes the subject matter of any of Examples 96-97, and further specifies that the capacitor includes multiple layers of ferroelectric or antiferroelectric material sandwiching the layer of dielectric material.

Example 99 includes the subject matter of Example 98, and further specifies that the multiple layers of ferroelectric or antiferroelectric material have a same material composition.

Example 100 includes the subject matter of any of Examples 78-99, and further specifies that at least one of the electrodes includes titanium and nitrogen.

Example 101 includes the subject matter of Example 100, and further specifies that at least one of the electrodes includes silicon.

Example 102 includes the subject matter of any of Examples 78-99, and further specifies that at least one of the electrodes includes tantalum and nitrogen.

Example 103 includes the subject matter of any of Examples 78-99, and further specifies that at least one of the electrodes includes copper, aluminum, gold, tungsten, cobalt, platinum, iridium, or ruthenium.

Example 104 includes the subject matter of any of Examples 78-103, and further specifies that the electrodes have a same material composition.

Example 105 includes the subject matter of any of Examples 78-104, and further specifies that at least one of the electrodes has a thickness between 10 nanometers and 50 nanometers.

Example 106 includes the subject matter of Example 105, and further specifies that both of the electrodes have a thickness between 10 nanometers and 50 nanometers.

Example 107 includes the subject matter of any of Examples 78-106, and further specifies that the both of the electrodes are planar.

Example 108 includes the subject matter of any of Examples 78-106, and further specifies that one of the electrodes includes a trench and the layer of dielectric material and the layer of ferroelectric or antiferroelectric material are at least partially in the trench.

Example 109 includes the subject matter of Example 108, and further specifies that an other of the electrodes includes a projection that extends at least partially into the trench.

Example 110 includes the subject matter of any of Examples 78-106, and further specifies that one of the electrodes includes a plurality of trenches and the layer of dielectric material and the layer of ferroelectric or antiferroelectric material are at least partially in the plurality of trenches.

Example 111 includes the subject matter of Example 110, and further specifies that an other of the electrodes includes a plurality of projections, wherein an individual projection extends at least partially into an associated individual trench.

Example 112 includes the subject matter of any of Examples 78-111, and further specifies that the memory cells are part of an array of memory cells.

Example 113 includes the subject matter of any of Examples 78-112, and further specifies that the memory device is a dynamic random access memory device.

Example 114 includes the subject matter of any of Examples 78-113, and further includes: a circuit board, wherein the IC package is coupled to the circuit board.

Example 115 includes the subject matter of Example 114, and further specifies that the circuit board and the IC package are coupled via solder.

Example 116 includes the subject matter of any of Examples 114-115, and further specifies that the circuit board is a motherboard.

Example 117 includes the subject matter of any of Examples 78-116, and further specifies that the computing device is a tablet computing device, a handheld computing device, a wearable computing device, or a server computing device.

Example 118 includes the subject matter of any of Examples 78-117, and further includes: wireless communication circuitry communicatively coupled to the IC package.

Example 119 includes the subject matter of any of Examples 78-118, and further includes: a display communicatively coupled to the IC package.

Example 120 is a method of manufacturing an integrated circuit (IC) structure, including: forming a first electrode of a capacitor; forming a layer of dielectric material of the capacitor; forming a layer of ferroelectric or antiferroelectric material of the capacitor; and forming a second electrode of the capacitor, wherein the layer of dielectric material and the layer of ferroelectric or antiferroelectric material are between the first electrode and the second electrode.

Example 121 includes the subject matter of Example 120, and further includes: forming a transistor; and forming interconnects between the transistor and the capacitor.

1. A capacitor, comprising:
a first electrode;
a second electrode; and
an inter-electrode stack between the first electrode and the second electrode, wherein the inter-electrode stack includes a first layer including a first material, the inter-electrode stack includes a second layer including a second material, the first material is a dielectric material, and the second material is a ferroelectric material or an antiferroelectric material.

2. The capacitor of claim 1, wherein the second material includes silicon, lanthanum, nitrogen, aluminum, zirconium, or germanium.

3. The capacitor of claim 1, wherein the second material includes hafnium and yttrium.

4. The capacitor of claim 1, wherein the second material is a ferroelectric material.

5. The capacitor of claim 1, wherein the second material is an antiferroelectric material.

6. The capacitor of claim 1, wherein the inter-electrode stack further includes a third layer, the second layer is between the first layer and the third layer, and the third layer includes a dielectric material.

7. The capacitor of claim 6, wherein the third layer includes the first material.

8. The capacitor of claim 6, wherein the inter-electrode stack further includes a fourth layer, the third layer is between the second layer and the fourth layer, and the fourth layer includes a ferroelectric material or an antiferroelectric material.

9. The capacitor of claim 8, wherein the fourth layer includes the second material.

10. The capacitor of claim 1, wherein the inter-electrode stack further includes a third layer, the first layer is between the second layer and the third layer, and the third layer includes a ferroelectric material or an antiferroelectric material.

11. The capacitor of claim 10, wherein the third layer includes the second material.

12. An integrated circuit (IC) die, comprising:
a capacitor, including:
a first electrode,
a second electrode, and
an inter-electrode stack between the first electrode and the second electrode, wherein the inter-electrode stack includes a first layer including a first material, the inter-electrode stack includes a second layer including a second material, the first material is a dielectric material, and the second material is a ferroelectric material or an antiferroelectric material.

13. The IC die of claim 12, wherein the first electrode is planar, and the second electrode is planar.

14. The IC die of claim 12, wherein the first electrode includes a trench and the inter-electrode stack is at least partially in the trench.

15. The IC die of claim 14, wherein the second electrode includes a projection that extends at least partially into the trench.

16. The IC die of claim 12, wherein the first electrode includes a plurality of trenches and the inter-electrode stack is at least partially in the plurality of trenches.

17. The IC die of claim 16, wherein the second electrode includes a plurality of projections, wherein an individual projection extends at least partially into an associated individual trench.

18. The IC die of claim 12, further comprising:
a transistor coupled to the capacitor.

19. A computing device, comprising:
an integrated circuit (IC) package including a memory device, wherein the memory device includes a plurality of memory cells, and an individual one of the memory cells includes:
a transistor, and
a capacitor including two electrodes, a layer of ferroelectric or antiferroelectric material between the electrodes, and a layer of dielectric material between the electrodes.

20. The computing device of claim 19, wherein the memory device is a dynamic random access memory device.
